(19) United States
(12) Patent Application Publication
(10) Pub. No.: US 2004/0239384 A1
(43) Pub. Date: Dec. 2, 2004

(54) Interface circuit

(76) Inventors: Denis Cottin, Crolles (FR); Sebastien Dedieu, Crolles (FR)

Correspondence Address: WOLF GREENFIELD & SACKS, PC, FEDERAL RESERVE PLAZA, 600 ATLANTIC AVENUE, BOSTON, MA, 02210-2211, US

(21) Appl. No.: 10/789,806

(22) Filed: Feb. 27, 2004

(30) Foreign Application Priority Data
Feb. 27, 2003 (FR) 0302422

(51) Int. Cl. H03B 1/00

(52) U.S. Cl. 327/148

(57) ABSTRACT

An interface circuit comprising one or two input branches and one output branch, each branch being connected between upper and lower supply terminals, each input branch comprising a transistor having its control electrode connected to the input of the interface circuit, one of the two other electrodes of the transistor being connected to one of the supply terminals, a current source being placed between the other one of the supply terminals and an intermediary node connected to the last transistor electrode possibly via one or several diodes, the output branch comprising two complementary transistors having their control electrodes connected to the intermediary nodes of one of the input branches or to the circuit input, one of the electrodes of each of the complementary transistors being connected to the circuit output, the last electrode of each of the transistors being connected to a supply terminal.

### FIELD OF THE INVENTION

The present invention relates to the field of integrated circuits.

The present invention relates to interface circuits enabling copying a variable voltage signal with a possible predetermined voltage offset.

### DISCUSSION OF THE RELATED ART

A known example of such an interface circuit is a follower-assembled operational amplifier.

A disadvantage of this circuit is that, in the case where the charge circuit exhibits a low input impedance, it is necessary for the operational amplifier to be formed of very large transistors to ensure a proper voltage copying.

Another disadvantage of this circuit is that is does not enable copying a signal having a large voltage excursion. Indeed, according to the forming mode of the operational amplifier, when the input signal is close to one of the supply voltages, the output signal saturates.

Another disadvantage of this circuit is that it does not enable copying a signal with a constant offset.

### SUMMARY OF THE INVENTION

An object of the present invention is to provide a low-bulk interface circuit capable of controlling charge circuits exhibiting a small input impedance.

Another object of the present invention is to provide such an interface circuit capable of copying a signal exhibiting a large voltage excursion.

Another object of the present invention is to provide such an interface circuit capable of copying a signal with a constant offset.

To achieve these objects, an embodiment of the present invention provides a charge pump circuit comprising first and second transistors of a first type controlled by first complementary signals, third and fourth transistors of a second type controlled by second complementary signals, a first current source being placed between a higher voltage terminal and a first electrode of the first and second transistors, a second current source being placed between a lower voltage terminal and a first electrode of third and fourth transistors, the second electrodes of the first and third transistors being connected to the circuit output, the second electrodes of second and fourth transistors being connected to a reference node, the circuit output being connected to the input of an interface circuit, the output of the interface circuit being connected to the reference node, the interface circuit comprising two input branches and one output branch, each branch being connected between upper and lower supply terminals, each input branch comprising a transistor having its control electrode connected to the input of the interface circuit, one of the two other electrodes of the transistor being connected to one of the supply terminals, a current source being placed between the other one of the supply terminals and an intermediate node connected to the last transistor electrode, the output branch comprising two complementary transistors, having their control electrodes connected to the intermediary nodes of the two input branches, one of the electrodes of each of the complementary transistors being connected to the interface circuit output, the last electrode of each of the transistors being connected to a supply terminal.

An other embodiment of the present invention provides an interface circuit comprising one or two input branches and one output branch, each branch being connected between upper and lower supply terminals, each input branch comprising a transistor having its control electrode connected to the input of the interface circuit, one of the two other electrodes of the transistor being connected to one of the supply terminals, a current source being placed between the other one of the supply terminals and an intermediary node connected to the last transistor electrode, at least one of the two input branches comprising one or several diodes connected between the intermediary node and the last transistor electrode of a considered branch, the output branch comprising two complementary transistors having their control electrodes connected to the intermediary nodes of one of the input branches or to the circuit input, one of the electrodes of each of the complementary transistors being connected to the circuit output, the last electrode of each of the transistors being connected to a supply terminal.

In an embodiment of the above-mentioned circuits, the transistors are CMOS transistors, the control electrode of a transistor being its gate, the two other electrodes being its source and drain, and the output branch comprises a PMOS transistor and an NMOS transistor, the drains of the PMOS and NMOS transistors being connected to the interface circuit output, the source of the PMOS transistor being connected to the upper supply terminal, the source of the NMOS transistor being connected to the lower supply terminal.

In an embodiment of the above-mentioned circuits, the source of each of the circuit transistors is connected to the transistor substrate.

In an embodiment of the above-mentioned circuits, the transistors are bipolar transistors, the control electrode of a transistor being its base, the two other electrodes beings its emitter and collector.

In an embodiment of the above-mentioned interface circuit, the circuit has a single input branch, the input branch comprising a PMOS transistor having its drain connected to the lower terminal and its gate connected to the input of the interface circuit, the source of the PMOS transistor being connected to a cathode of a diode, the current source of the input branch being placed between the anode of the diode and the upper supply terminal, the gate of the NMOS transistor of the output branch being connected to the source of the PMOS transistor of the input branch, the gate of the PMOS transistor of the output branch being connected to the circuit input.

In an embodiment of the above-mentioned interface circuit, the circuit comprises first and second input branches, the first input branch comprising an NMOS transistor having its drain connected to the upper supply terminal, the current source of the first input branch being placed between the source of the NMOS transistor of the first input branch and the lower supply terminal, the second input branch comprising an NMOS transistor having its drain connected to the upper supply terminal, the source of the NMOS transistor of the second branch being connected to the anode of a first diode, the cathode of the first diode being connected to the anode of a second diode, the current source of the second input branch being placed between the cathode of the second diode and the lower supply terminal, the gates of the NMOS transistors of the first and second input branches being connected to the input of the interface circuit, the gate of the NMOS transistor of the output branch being connected to the source of the NMOS transistor of the first input branch, the gate of the PMOS transistor of the output branch being connected to the cathode of the second diode.

In an embodiment of the above-mentioned charge pump circuit, the first and second transistors are PMOS transistors and the third and fourth transistors are NMOS transistors, and the interface circuit comprises first and second input branches, a first input branch comprising a PMOS transistor having its drain connected to the lower supply terminal, the current source of the first input branch being placed between the source of the PMOS transistor of the first input branch and the upper supply terminal, the second input branch comprising an NMOS transistor having its drain connected to the upper supply terminal, the current source of the second input branch being placed between the source of the NMOS transistor and the lower supply terminal, the gates of the NMOS and PMOS transistors of the first and second input branches being connected to the interface circuit input, the gate of the NMOS transistor of the output branch being connected to the source of the PMOS transistor of the first input branch, the gate of the PMOS transistor of the output branch being connected to the source of the NMOS transistor of the second input branch.

The foregoing objects, features, and advantages of the present invention will be discussed in detail in the following non-limiting description of specific embodiments in connection with the accompanying drawings.

### BRIEF DESCRIPTION OF THE DRAWINGS

FIG. 1 shows an interface circuit;

FIG. 2 shows an interface circuit according to an embodiment of the present invention;

FIG. 3 shows an interface circuit according to an embodiment of the present invention; and

FIG. 4 shows a charge pump circuit according to the present invention.

### DETAILED DESCRIPTION

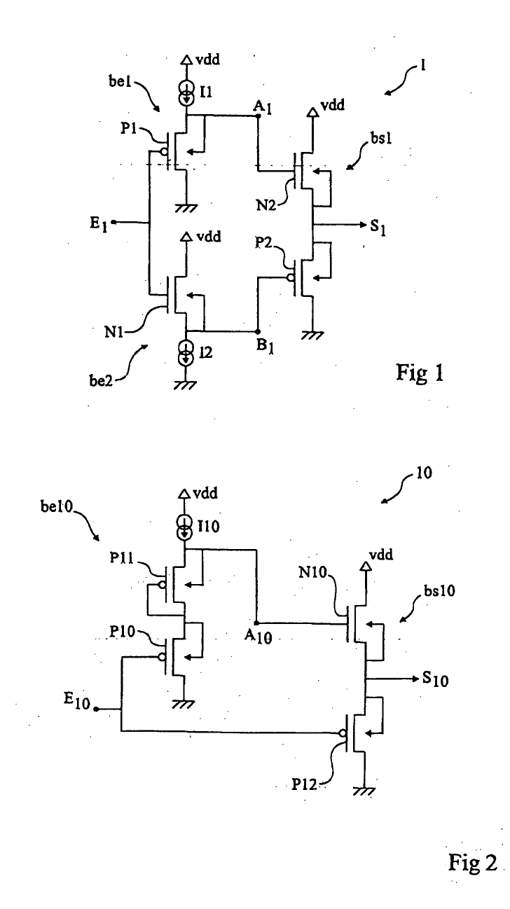

FIG. 1 is a diagram of an interface circuit. Interface circuit 1 comprises two input branches be1 and be2 and one output branch bs1. Each of the branches is placed between a positive supply terminal vdd and ground gnd, terminal vdd being for example 2.5 volts. Input branch be1 comprises a PMOS transistor P1 and a current source I1. The drain of transistor P1 is grounded. Current source I1 is placed between terminal vdd and the source of transistor P1. The gate of transistor P1 is connected to input E₁ of interface circuit 1. Input branch be2 comprises an NMOS transistor N1 and a current source I2. The drain of transistor N1 is connected to terminal vdd. Current source I2 is placed between the ground and the source of transistor N1. The gate of transistor N1 is connected to input E₁. Output branch bs1 comprises an NMOS transistor N2 and a PMOS transistor P2. The gate of transistor N2 is connected to junction point A₁ of current source I1 with the source of transistor P1. The gate of transistor P2 is connected to junction point B₁ of current source I2 with the source of transistor N1. The drain of transistor N2 is connected to terminal vdd and the drain of transistor P2 is grounded. The sources of transistors N2 and P2 are connected to output S₁ of interface circuit 1.

In standard CMOS circuits, threshold voltage Vtp of a PMOS transistor is substantially equal to threshold voltage Vtn of an NMOS transistor. It will be considered in the following description that threshold voltages Vtp and Vtn are equal to a single threshold voltage Vt.

Voltage Va₁ at node A₁ is substantially equal to voltage Ve₁ on input E₁ plus one threshold voltage Vt. Similarly, voltage Vb₁ at node B₁ is substantially equal to voltage Ve₁ minus one threshold voltage Vt. Transistor N2 is on when voltage Vs₁ on output S₁ is smaller than voltage Va₁ minus one threshold voltage Vt. Transistor P2 is on when voltage Vs₁ is greater than voltage Vb₁ plus one threshold voltage Vt. The difference between voltages Va₁ and Vb₁ is equal to twice threshold voltage Vt. Voltage Vs₁ then is equal to (Va₁+Vb₁)/2 and is equal to Ve₁.

When voltage Ve₁ increases, voltages Va₁ and Vb₁ increase. Transistor P2 turns off and transistor N2 is on. Voltage Vs₁ increases. Conversely, when voltage Ve₁ decreases, voltages Va₁ and Vb₁ decrease. Transistor N2 turns off and transistor P2 is on. Voltage Vs₁ decreases.

To provide constant threshold voltages and thus ensure a better copying of the signal provided on input E₁, it may be provided for each of the transistors of the interface circuit to connect their source to the substrate area located under their gate, as illustrated in FIG. 1. For this purpose, the interface circuit transistors must have an insulated and independent substrate.

Further, preferably, the size of the transistor of each input branch is adjusted to the current source to which it is connected so that the gate/source voltages of transistors N1 and P1 are identical and for example close to threshold voltage Vt, when the transistors are in saturation and conduct a current equal to that provided by their respective current source.

FIG. 2 is a diagram of an interface circuit 10 according to an embodiment of the present invention. Circuit 10 comprises an input branch be10 and an output branch bs10 placed between a positive supply terminal vdd and ground gnd. Input branch be10 comprises two PMOS transistors P10 and P11 and one current source I10. The drain of transistor P10 is grounded. The gate of transistor P10 is connected to input E₁₀ of interface circuit 10. Transistor P11 is diode-assembled, its gate being connected to its drain. The drain of transistor P11 is connected to the source of transistor P10. Current source I10 is placed between terminal vdd and the source of transistor P11. Output branch bs10 comprises an NMOS transistor N10 and a PMOS transistor P12. The drain of transistor N10 is connected to terminal vdd. The drain of transistor P12 is grounded. The sources of transistors N10 and P12 are connected to output S₁₀ of interface circuit 10. The gate of transistor N10 is connected to intermediary point A₁₀ between current source I10 and the source of transistor P11. The gate of transistor P12 is connected to input E₁₀.

Voltage Va₁₀ at point A₁₀ is equal to voltage Ve₁₀ on input E₁₀ plus twice threshold voltage Vt. Indeed, when both transistors P11 and P10 are on, the gate/source (or source/drain) voltage of transistor P11 is substantially equal to one threshold voltage Vt and the source/gate voltage of transistor P10 is also substantially equal to one threshold voltage Vt. This is verified in the case, as previously, where the sizes of transistors P10 and P11 are provided for the source/gate voltages to be close to Vt when they conduct a current equal to that provided by current source I10. Voltage Vs₁₀ on output S₁₀ is equal to the average of voltages Va₁₀ and Ve₁₀ which is equal to voltage Ve₁₀ plus one threshold voltage Vt. Whatever voltage Ve₁₀, output voltage Vs₁₀ is thus always equal to voltage Ve₁₀ plus one threshold voltage Vt.

To, as previously, ensure a correct offset copying whatever the value of voltage Ve₁₀, the source of each transistor is connected to the substrate area located under their gate as shown in FIG. 2.

Interface circuit 10 enables copying a signal with a “positive” voltage offset, the output signal being increased by one threshold voltage Vt. In dual fashion, it is possible to form an interface circuit enabling copy of a signal with a negative offset, the output signal being decreased by one threshold voltage Vt. Such an interface circuit comprises a single input branch formed of two NMOS transistors and of one current source. The gate of one of the NMOS transistors is connected to the interface circuit input. The drain of this same transistor is connected to a positive supply terminal vdd and its source is connected to the second diode-assembled NMOS transistor. The current source is placed between the diode-assembled transistor and ground gnd. The interface circuit comprises an output branch identical to that of interface circuit 10. The gate of the NMOS transistor of the output branch is connected to the interface circuit input. The gate of the PMOS transistor of the output branch is connected to the junction point of the current source with the diode-assembled NMOS transistor of the input branch.

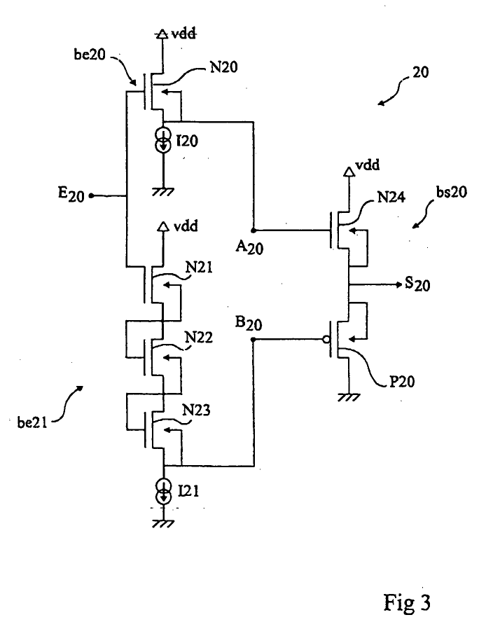

FIG. 3 is a diagram of an interface circuit 20 according to an embodiment of the present invention. Interface circuit 20 comprises two input branches be20 and be21 and one output branch bs20. Input branch be20 comprises an NMOS transistor N20 and a current source I20. The drain of transistor N20 is connected to terminal vdd. Current source I20 is placed between the source of transistor N20 and the ground. The gate of transistor N20 is connected to input E₂₀ of interface circuit 20. Input branch be21 comprises three NMOS transistors N21, N22, and N23, and one current source I21. The drain of transistor N21 is connected to terminal vdd. The gate of transistor N21 is connected to input E₂₀. Transistors N22 and N23 are diode-assembled, their gate being connected to their drain. The drain of transistor N22 is connected to the source of transistor N21 and the drain of transistor N23 is connected to the source of transistor N22. Current source I21 is placed between the source of transistor N23 and the ground. Output branch bs20 comprises an NMOS transistor N24 and a PMOS transistor P20. The drain of transistor N24 is connected to terminal vdd. The drain of transistor P20 is grounded. The sources of transistors N24 and P20 are connected to output S₂₀ of interface circuit 20. The gate of transistor N24 is connected to junction point A₂₀ of the source of transistor N20 with current source I20. The gate of transistor P20 is connected to junction point B₂₀ of the source of transistor N23 with current source I21.

Voltage Va₂₀ at point A₂₀ is equal to voltage Ve₂₀ on input E₂₀ minus one threshold voltage Vt. Voltage Vb₂₀ at node B₂₀ is equal to voltage Ve₂₀ minus three times threshold voltage Vt. Accordingly, voltage Ve₂₀ on output S₂₀ is equal to voltage Ve₂₀ minus twice threshold voltage Vt.

Interface circuit 20 enables copying a signal with a negative voltage offset equal to twice threshold voltage Vt. In dual fashion, it is possible to form an interface circuit enabling copy of a signal with a positive voltage offset equal to twice threshold voltage Vt.

Generally, an interface circuit according to the present invention comprises one or several input branches and a single output branch. Each input branch comprises a current source and a transistor controlled by the input signal as well as one or several diodes. The single output branch is formed of an NMOS transistor and of a PMOS transistor assembled in “push-pull” as described previously in relation with FIGS. 1 to 3. The NMOS and PMOS transistors of the output branch receive control voltages offset with respect to each other by a voltage substantially equal to twice threshold voltage Vt. In the case where a control voltage is to be offset with respect to the input signal voltage, the adequate control voltage is provided by an input branch. Thus, in the case where a control voltage greater than the voltage of the input signal is desired to be obtained, an input branch comprising a PMOS transistor controlled by the input signal will be provided, its drain being connected to ground and its source being connected to a current source possibly via one or several diodes. In the case where a control voltage smaller than the input signal voltage is desired to be obtained, an input branch comprising an NMOS transistor controlled by the input signal will be provided, its drain being connected to terminal vdd and its source being connected to a current source possibly via one or several diodes.

An advantage of the interface circuit according to the present invention is that it enables copying signals exhibiting a large voltage excursion. The limiting values of the input signal voltage range for which the copy is correct are a function of the interface circuit. In the case of interface circuit 1 of FIG. 1, the limiting values are vdd-Vt and gnd+Vt (vdd being a high voltage and gnd a low voltage, for example, the ground). In the case of interface circuit 10 of FIG. 2, the limiting values are gnd and vdd-2Vt. In the case of interface circuit 20 of FIG. 3, the limiting values are vdd and gnd+3Vt.

Another advantage of the interface circuit of the present invention is that is enables copying a signal with a constant offset.

Further, the input branches have a small charge impedance corresponding to the gate capacitance of a transistor of the output branch. Accordingly, the transistors of the input branches may be of small size. Further, the transistors of the output branch are controlled so that in static mode, when the input signal does not vary, the transistors are very lightly conductive. Conversely to a follower-assembled amplifier, the static consumption of an interface circuit according to the present invention is very small. Further, the “push-pull” assembly of the transistors of the output branch is such that in dynamic mode, when the input signal varies, a single transistor is on. The entire current provided or absorbed by the on transistor is used to increase or decrease the output voltage. Accordingly, for an equivalent supplied power, an interface circuit according to the present invention can be formed with transistors of small size.

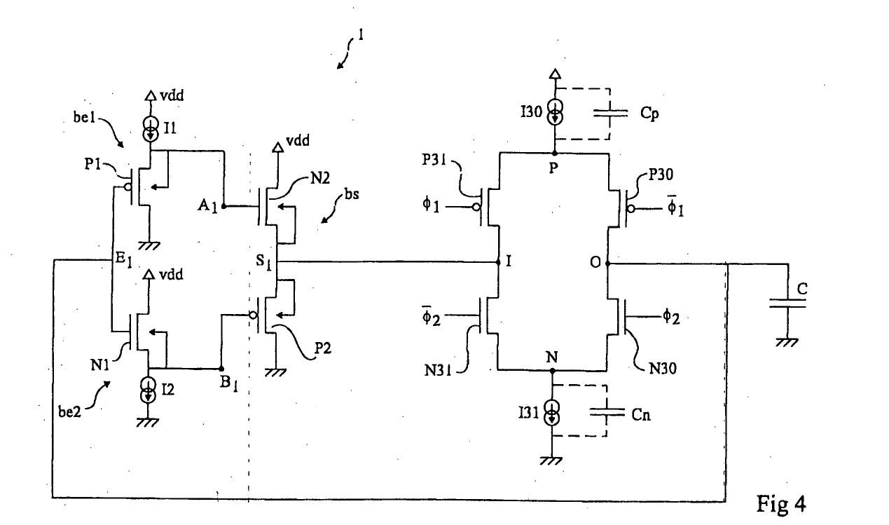

FIG. 4 is a diagram of a charge pump circuit according to the present invention which comprises an interface circuit such as described in relation with FIG. 1. The charge pump circuit for example belongs to a phase-locked loop circuit or PLL. The charge pump circuit comprises two PMOS transistors P30 and P31 and two NMOS transistors N30 and N31. A current source I30 is placed between terminal vdd and a node P connected to the sources of transistors P30 and P31. A current source I31 is placed between the ground and a node N connected to the sources of transistors N30 and N31. The drains of transistors P30 and N30 are connected to output O of the charge pump circuit. The drains of transistors P31 and N31 are connected to a node I. Transistor P31 is controlled by a signal φ1 and transistor P31 is controlled by a signal ^{\overline{φ1}} complementary to signal φ1. Transistor N30 is controlled by a signal φ2 and transistor N31 is controlled by a signal ^{\overline{φ2}} complementary to signal φ2. This circuit is intended to charge or discharge a capacitor C placed between output O and the ground. Interface circuit 1 is placed between nodes I and O. Output O of the charge pump circuit is connected to input E₁ of interface circuit 1. Output S₁ of interface circuit 1 is connected to node I.

Output O of the charge pump circuit controls, possibly via a filter circuit, a voltage-controlled oscillator belonging to the phase-locked loop circuit. As an example, when voltage Vo on output O increases, the oscillator frequency increases, and conversely. Signals φ1, ^{\overline{φ1}}, φ2 and ^{\overline{φ2}} are generated by a circuit for detecting the phase shift between a reference clock signal and a signal equal to the signal generated by the voltage-controlled oscillator and divided by a number N.

When signal φ1 is active, equal to vdd, and signal φ2 is inactive, equal to gnd, transistor P30 is on and transistor N30 is off. Capacitor C charges and voltage Vo increases. The oscillator frequency increases. Conversely, when signal φ2 is active and signal φ1 is inactive, transistor N30 is on and transistor P30 is off. Capacitor C discharges and voltage Vo decreases. The oscillator frequency decreases. When signals φ1 and φ2 are both active or both inactive, voltage Vo does not vary and the oscillator frequency remains unchanged.

When transistor P30 is off, transistor P31 is on and it maintains node P at the voltage that it would have if transistor P30 was on, since the voltages at nodes I and O are equal. Similarly, when transistor N30 is off, transistor N31 is on and it maintains node N at the voltage that it would have if transistor N30 was on.

As will appear hereafter, the above-described charge pump circuit has a significant advantage as compared to a conventional charge pump circuit comprising no interface circuit according to the present invention to supply the drains of transistors P31 and N31 with a voltage equal to that of output O of the charge pump circuit.

Indeed, in a conventional charge pump circuit, the drains of transistors P31 and N31 are respectively connected to ground and to terminal vdd. When “hold” transistors P31 and N31 are active, nodes N and P are at an intermediary voltage between the ground and the voltage of terminal vdd, the intermediary voltage depending on the size of transistors P31 and N31 and on the current provided by sources I30 and I31. Generally, complementary signals φ1/^{\overline{φ1}} and φ2/^{\overline{2}} switch with a slight delay with respect to each other, so that, in principle, both transistors are off before inverting the selection. At the time when transistor N30 turns back on, the voltage at node N varies according to the order and to the switching duration of transistors N30 and N31. However, whatever the variations of the voltage at node N during the switching, the voltage after switching is always smaller than the voltage before switching, the voltage after switching being all the smaller as the voltage at node O is small. Similarly, at the time when transistor P30 turns back on, the voltage at node P after switching is always higher than the voltage before switching, the voltage after switching being all the higher as the voltage at node O is high. Now, current sources I30 and I31 exhibit stray capacitances, respectively Cp and Cn such as shown in dotted lines in FIG. 4. When the voltage at node P increases, capacitor Cp must discharge and the provided charge current is given the value of the discharge current. Similarly, when the voltage at node N decreases, capacitor Cp must discharge and the discharge current absorbed by source I30 is given the value of the discharge current of capacitor Cp. Since the charge or discharge current is not strictly equal to the current provided by current sources I30 and I31, the voltage at node O does not vary in the desired proportions, which adversely affects the proper operation of the phase-locked loop circuit. Further, when one of transistors P30 and N30 turns on while the other one was already on, the parasitic charge or discharge current causes parasitic overvoltages or undervoltages which untimely vary voltage Vo. The errors induced by such parasitic phenomena are all the greater as the operation of the phase-shift detection circuit is such that it controls frequent switchings of signals φ1 and φ2.

Conversely to the conventional charge pump circuit, the charge pump circuit of FIG. 4 comprising an interface circuit according to the present invention is such that whatever the order and the switching durations of transistor pairs N30/N31 and P30/P31 upon switching of signals φ1 and φ2, the voltages at node N or P before and after the switching are equal. All the parasitic phenomena described hereabove for a conventional circuit are non-existent in the circuit of FIG. 4.

An advantage of the charge pump circuit according to the present invention is that it enables varying the oscillator control voltage in accordance with the control signals of the phase-shift detection circuit, especially when the control signals vary with a high frequency.

Of course, the present invention is likely to have various alterations, modifications, and improvements which will readily occur to those skilled in the art. In particular, an interface circuit according to the present invention may be formed with BICMOS transistors. Generally, the NMOS transistors of the described circuits may be replaced with NPN transistors and the PMOS transistors may be replaced with PNP transistors. Similarly, the previously-described charge pump circuit may be formed with bipolar transistors.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

What is claimed is:

1. A charge pump circuit comprising first and second transistors of a first type controlled by first complementary signals, third and fourth transistors of a second type controlled by second complementary signals, a first current source being placed between a higher voltage terminal and a first electrode of the first and second transistors, a second current source being placed between a lower voltage terminal and a first electrode of third and fourth transistors, the second electrodes of the first and third transistors being connected to the circuit output, the second electrodes of second and fourth transistors being connected to a reference node, the circuit output being connected to the input of an interface circuit, the output of the interface circuit being connected to the reference node, the interface circuit comprising two input branches and one output branch, each branch being connected between upper and lower supply terminals, each input branch comprising a transistor having its control electrode connected to the input of the interface circuit, one of the two other electrodes of the transistor being connected to one of the supply terminals, a current source being placed between the other one of the supply terminals and an intermediate node connected to the last transistor electrode, the output branch comprising two complementary transistors, having their control electrodes connected to the intermediary nodes of the two input branches, one of the electrodes of each of the complementary transistors being connected to the interface circuit output, the last electrode of each of the transistors being connected to a supply terminal.

2. An interface circuit comprising one or two input branches and one output branch, each branch being connected between upper and lower supply terminals, each input branch comprising a transistor having its control electrode connected to the input of the interface circuit, one of the two other electrodes of the transistor being connected to one of the supply terminals, a current source being placed between the other one of the supply terminals and an intermediary node connected to the last transistor electrode, at least one of the two input branches comprising one or several diodes connected between the intermediary node and the last transistor electrode of a considered branch, the output branch comprising two complementary transistors having their control electrodes connected to the intermediary nodes of one of the input branches or to the circuit input, one of the electrodes of each of the complementary transitors being connected to the circuit output the last electrode of each of the transistors being connected to a supply terminal.

3. The circuit of claim 1, wherein the transistors are CMOS transistors, the control electrode of a transistor being its gate, the two other electrodes being its source and drain, and wherein the output branch comprises a PMOS transistor and an NMOS transistor, the drains of the PMOS and NMOS transistors being connected to the interface circuit output, the source of the PMOS transistor being connected to the upper supply terminal, the source of the NMOS transistor being connected to the lower supply terminal.

4. The circuit of claim 3, wherein the source of each of the circuit transistors is connected to the transistor substrate.

5. The circuit of claim 1, wherein the transistors are bipolar transistors, the control electrode of a transistor being its base, the two other electrodes beings its emitter and collector.

6. The interface circuit of claim 2, having a single input branch, the input branch comprising a PMOS transistor having its drain connected to the lower terminal and its gate connected to the input of the interface circuit, the source of the PMOS transistor being connected to a cathode of a diode, the current source of the input branch being placed between the anode of the diode and the upper supply terminal, the gate of the NMOS transistor of the output branch being connected to the source of the PMOS transistor of the input branch, the gate of the PMOS transistor of the output branch being connected to the circuit input.

7. The interface circuit of claim 2, comprising first and second input branches, the first input branch comprising an NMOS transistor having its drain connected to the upper supply terminal, the current source of the first input branch being placed between the source of the NMOS transistor of the first input branch and the lower supply terminal, the second input branch comprising an NMOS transistor having its drain connected to the upper supply terminal, the source of the NMOS transistor of the second branch being connected to the anode of a first diode, the cathode of the first diode being connected to the anode of a second diode, the current source of the second input branch being placed between the cathode of the second diode and the lower supply terminal, the gates of the NMOS transistors of the first and second input branches being connected to the input of the interface circuit, the gate of the NMOS transistor of the output branch being connected to the source of the NMOS transistor of the first input branch, the gate of the PMOS transistor of the output branch being connected to the cathode of the second diode.

8. A charge pump circuit of claim 1, wherein the first and second transistors are PMOS transistors and the third and fourth transistors are NMOS transistors, and wherein the interface circuit comprises first and second input branches, a first input branch comprising a PMOS transistor having its drain connected to the lower supply terminal, the current source of the first input branch being placed between the source of the PMOS transistor of the first input branch and the upper supply terminal, the second input branch comprising an NMOS transistor having its drain connected to the upper supply terminal, the current source of the second input branch being placed between the source of the NMOS transistor and the lower supply terminal, the gates of the NMOS and PMOS transistors of the first and second input branches being connected to the interface circuit input, the gate of the NMOS transistor of the output branch being connected to the source of the PMOS transistor of the first input branch, the gate of the PMOS transistor of the output branch being connected to the source of the NMOS transistor of the second input branch.

9. The circuit of claim 2, wherein the transistors are CMOS transistors, the control electrode of a transistor being its gate, the two other electrodes being its source and drain, and wherein the output branch comprises a PMOS transistor and an NMOS transistor, the drains of the PMOS and NMOS transistors being connected to the interface circuit output, the source of the PMOS transistor being connected to the upper supply terminal, the source of the NMOS transistor being connected to the lower supply terminal.

10. The circuit of claim 9, wherein the source of each of the circuit transistors is connected to the transistor substrate.

11. The circuit of claim 2, wherein the transistors are bipolar transistors, the control electrode of a transistor being its base, the two other electrodes beings its emitter and collector.

12. The interface circuit of claim 9, having a single input branch, the input branch comprising a PMOS transistor having its drain connected to the lower terminal and its gate connected to the input of the interface circuit, the source of the PMOS transistor being connected to a cathode of a diode, the current source of the input branch being placed between the anode of the diode and the upper supply terminal, the gate of the NMOS transistor of the output branch being connected to the source of the PMOS transistor of the input branch, the gate of the PMOS transistor of the output branch being connected to the circuit input.

13. The interface circuit of claim 9, comprising first and second input branches, the first input branch comprising an NMOS transistor having its drain connected to the upper supply terminal, the current source of the first input branch being placed between the source of the NMOS transistor of the first input branch and the lower supply terminal, the second input branch comprising an NMOS transistor having its drain connected to the upper supply terminal, the source of the NMOS transistor of the second branch being connected to the anode of a first diode, the cathode of the first diode being connected to the anode of a second diode, the current source of the second input branch being placed between the cathode of the second diode and the lower supply terminal, the gates of the NMOS transistors of the first and second input branches being connected to the input of the interface circuit, the gate of the NMOS transistor of the output branch being connected to the source of the NMOS transistor of the first input branch, the gate of the PMOS transistor of the output branch being connected to the cathode of the second diode.
are PMOS transistors and the third and fourth transistors are NMOS transistors, and wherein the interface circuit comprises first and second input branches, a first input branch comprising a PMOS transistor having its drain connected to the lower supply terminal, the current source of the first input branch being placed between the source of the PMOS transistor of the first input branch and the upper supply terminal, the second input branch comprising an NMOS transistor having its drain connected to the upper supply terminal, the current source of the second input branch being placed between the source of the NMOS transistor and the lower supply terminal, the gates of the NMOS and PMOS transistors of the first and second input branches being connected to the interface circuit inpu, the gate of the NMOS transistor of the output branch being connected to the source of the PMOS transistor of the first input branch, the gate of the PMOS transistor of the output branch being connected to the source of the NMOS transistor of the second input branch.
